(19) United States
(12) Patent Application Publication
(10) Pub. No.: US 2018/0327895 A1
(43) Pub. Date: Nov. 15, 2018

(54) EVAPORATION APPARATUS

(71) Applicant: Junying MU, Wuhan, Hubei (CN)

(72) Inventor: Junying MU, Wuhan, Hubei (CN)

(21) Appl. No.: 15/574,344

(22) PCT Filed: Aug. 8, 2017
(86) PCT No.: PCT/CN2017/096369

§ 371 Date: Nov. 15, 2017

(30) Foreign Application Priority Data
May 12, 2017 (CN) 201710335856.8

(51) Int. Cl. C23C 14/24

(52) U.S. Cl. CPC C23C 14/243

(57) ABSTRACT

An evaporating apparatus includes a plurality of evaporation sources, and each includes a material chamber, a nozzle, and restriction plates disposed on both sides of each of the evaporation sources, wherein a distance and a height difference between the adjacent restriction plates limit a spray range of the nozzle between the adjacent restriction plates, each of the restriction plates is connected with a moving assembly, and each of the restriction plates is movable within a region between two of the adjacent evaporation sources via the moving assembly for adjusting the spray range of the nozzle.

### FIELD OF THE INVENTION

The present disclosure relates to an evaporation apparatus.

### BACKGROUND OF THE DISCLOSURE

Compared with current major liquid crystal display (LCD) technology, organic light emitting diode (OLED) display technology has high contrast, a wide color gamut, flexibility, lightweight, energy conservation, and other outstanding advantages. In recent years, OLED display technology has gradually been popularized in the fields of mobile devices, such as smart phones and tablets, flexible wearable devices, such as smart watches, large-sized curved televisions, and white lighting. The prospect of development thereof is promising.

The OLED technology mainly includes small molecular OLED technology which works using vacuum vapor deposition technology, and macromolecular OLED technology which works using solution processes. A vapor deposition machine is the main equipment for current mass production of small molecule OLED devices. A core of the equipment is an evaporation apparatus, which can be grouped into a point evaporation source, a linear evaporation source, and a surface evaporation source.

In order to control effective area of vapor deposition generated by the evaporation source, restriction plates are disposed on both sides of the evaporation source. Heights of the restriction plates are higher than heights of the nozzles of the evaporation source, so that part of the material is shielded for changing a spray range of the nozzle, and a sprayed material is prevented from exceeding range of the substrate.

However, in the conventional evaporation apparatus, the heights and the positions of the restriction plates are fixed, and therefore the spray ranges of the nozzles are fixed, and the area range where the different doped materials are deposited on the surface of the substrate cannot be adjusted.

### SUMMARY OF THE INVENTION

The present disclosure provides an evaporation apparatus including adjustable restriction plates. By adjusting the positions of the restriction plates, the area range where the different doped materials are deposited on the surface of the substrate can be adjusted, for resolving the technical problems that the heights and the positions of the restriction plates are fixed, the spray ranges of the nozzles are fixed, and the area range where the different doped materials are deposited on the surface of the substrate cannot be adjusted.

In order to resolve the above problems, the technical solution is provided in the present disclosure as follows:

An evaporating apparatus comprising:

a housing, and

a plurality of evaporation sources located in the housing for evaporating a material into a material vapor, and each including:

a material chamber for storing the material;

a heating member fixed onto an exterior of the material chamber for heating the material in the material chamber;

a nozzle located on an upper side of one of the evaporation sources for spraying the material vapor onto a surface of a substrate; and

a plurality of restriction plates disposed on both sides of each of the evaporation sources, wherein a height of each of the restriction plates is greater than a height of the nozzle, and wherein a distance and a height difference between the adjacent restriction plates limit a spray range of the nozzle between the adjacent restriction plates;

wherein each of the restriction plates is connected with a moving assembly, each of the restriction plates is movable within a region between two of the adjacent evaporation sources via the moving assembly for adjusting the spray range of the nozzle, each of the restriction plates is horizontally or vertically movable within the region between two of the evaporation sources via the moving assembly, and the moving assembly includes:

horizontal rails disposed at both ends of one of the evaporation sources and being parallel to a width direction of the evaporation sources; and

vertical rails being parallel to a height direction of the evaporation sources,

wherein a bottom of each of the vertical rails is slidably connected to one of the horizontal rails via a first drive motor, and each end of each of the restriction plates is slidably connected to one of the vertical rails via a second drive motor.

In accordance with a preferred embodiment of the present disclosure, the nozzle is a linear nozzle, the linear nozzle includes a plurality of linearly spaced ejection orifices, and a arrangement direction of the ejection orifices is perpendicular to a movement direction of the substrate.

In accordance with a preferred embodiment of the present disclosure, a top of each of the restriction plates is provided with a sub-plate, the sub-plate is perpendicular to one of the restriction plates, and a side portion of the sub-plate extends toward the upper side of the adjacent evaporation source.

In accordance with a preferred embodiment of the present disclosure, each of the restriction plates is removably provided with an elongated collection trough, the elongated collection trough is parallel to a bottom edge of one of the restriction plates, and two ends of the elongated collection trough are flush with two side edges of one of the restriction plates.

In accordance with a preferred embodiment of the present disclosure, each of the restriction plates is provided with a heating element.

In accordance with a preferred embodiment of the present disclosure, the two ends of the elongated collection trough arc provided with fixing members, and the fixing members are bent, disposed on sides of one of the restriction plates, and fixed by bolts.

In accordance with a preferred embodiment of the present disclosure, an arcuate transition surface is formed at a junction of the sub-plate and one of the restriction plates.

In accordance with a preferred embodiment of the present disclosure, said arcuate transition surface is an inner circular arcuate surface, one end of the arcuate transition surface is connected to an end of the sub plate, and other end of the arcuate transition surface is connected to a side of one of the restriction plates.

An evaporating apparatus is provided in the present disclosure, comprising:

a housing, and

a plurality of evaporation sources located in the housing for evaporating a material into a material vapor, and each including:

a material chamber for storing the material;

a heating member fixed onto exterior of the material chamber for heating the material in the material chamber;

a nozzle located on an upper side of one of the evaporation sources for spraying the material vapor onto a surface of a substrate; and

a plurality of restriction plates disposed on both sides of each of the evaporation sources, wherein a height of each of the restriction plates is greater than a height of the nozzle, and wherein a distance and a height difference between the adjacent restriction plates limit a spray range of the nozzle between the adjacent restriction plates;

wherein each of the restriction plates is connected with a moving assembly, each of the restriction plates is movable within a region between two of the adjacent evaporation sources via the moving assembly for adjusting the spray range of the nozzle.

In accordance with a preferred embodiment of the present disclosure, the nozzle is a linear nozzle, the linear nozzle includes a plurality of linearly spaced ejection orifices, and a arrange direction of the ejection orifices are arranged is perpendicular to a movement direction of the substrate.

In accordance with a preferred embodiment of the present disclosure, a top of each of the restriction plates is provided with a sub-plate, the sub-plate is perpendicular to one of the restriction plates, and a side portion of the sub-plate extends toward the upper side of the adjacent evaporation source.

In accordance with a preferred embodiment of the present disclosure, each of the restriction plates is removably provided with an elongated collection trough, the elongated collection trough is parallel to a bottom edge of one of the restriction plates, and two ends of the elongated collection trough are flush with two side edges of one of the restriction plates.

In accordance with a preferred embodiment of the present disclosure, each of the restriction plates is provided with a heating element.

In accordance with a preferred embodiment of the present disclosure, the two ends of the elongated collection trough are provided with fixing members, and the fixing members are bent, disposed on sides of one of the restriction plates, and fixed by bolts.

In accordance with a preferred embodiment of the present disclosure, an arcuate transition surface is formed at a junction of the sub-plate and one of the restriction plates.

In accordance with a preferred embodiment of the present disclosure, said arcuate transition surface is an inner circular arcuate surface, one end of the arcuate transition surface is connected to an end of the sub plate, and other end of the arcuate transition surface is connected to a side of one of the restriction plates.

The disclosure has the advantages as follows: compared with the conventional evaporation apparatus, the evaporation apparatus in the present disclosure has the movable restriction plates, and by adjusting the heights of the restriction plates and the distances between the restriction plates and the evaporation resources, the spray ranges of the nozzles is adjustable, and thereby the area range where the different doped materials on the surface of the substrate are deposited can be adjusted.

### BRIEF DESCRIPTION OF THE DRAWINGS

In order to more clearly illustrate the embodiments of the present disclosure or the technical solutions in prior arts, the following briefly introduces the accompanying drawings used in the embodiments. Obviously, the drawings in the following description merely show some of the embodiments of the present disclosure. As regards one of ordinary skill in the art, other drawings can be obtained in accordance with these accompanying drawings without making creative efforts.

FIG. 1 is a structural schematic diagram of an evaporation apparatus in the present disclosure.

FIG. 2A is a schematic diagram of the evaporation apparatus in a status of use in the present disclosure.

FIG. 2B is a schematic diagram of the evaporation apparatus in another status of use in the present disclosure.

### DETAILED DESCRIPTION OF THE PREFERRED EMBODIMENTS

The following description of the embodiments with reference to the accompanying drawings is used to illustrate particular embodiments of the present disclosure. The directional terms referred in the present disclosure, such as “upper”, “lower”, “front”, “back”, “left”, “right”, “inner”, “outer”, “side”, etc. are only directions with regard to the accompanying drawings. Therefore, the directional terms used for describing and illustrating the present disclosure are not intended to limit the present disclosure.

The present disclosure aims at the technical problems that the heights and the positions of the restriction plates are fixed, the spray ranges of the nozzles are fixed, and the area range on the surface of the substrate where the different doped materials are deposited cannot be adjusted. The present embodiment is capable of solving this drawback.

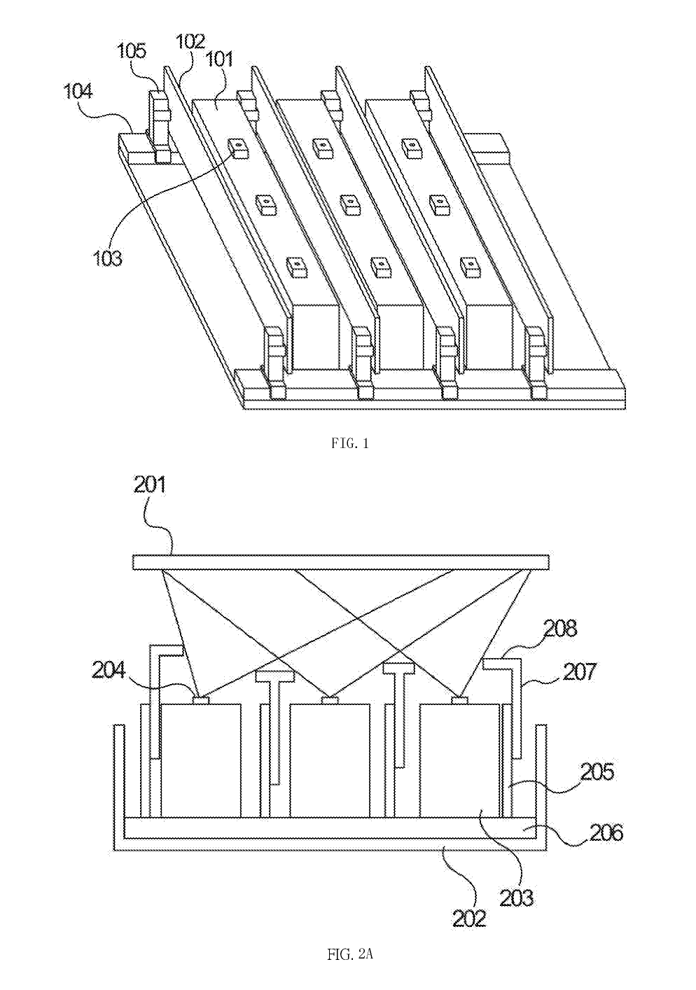

As shown in FIG. 1, the evaporation apparatus of the present disclosure includes a housing, a plurality of evaporation sources 101 located in the housing, a plurality of restriction plates 102 disposed on both sides of each of the evaporation sources 101.

Each of the evaporation sources 101 includes a material chamber, a heating member, and a nozzle 103. The material chamber is configured to store the material, the heating member is fixed onto an exterior of the material chamber for heating the material in the material chamber, and the nozzle 103 is located on an upper side of one of the evaporation sources for spraying the material vapor onto a surface of a substrate.

The evaporation sources 101 and the restriction plates 102 are plural. The evaporation sources 101 are alternately arranged with the restriction plates 102. Each of the evaporation sources 101 is disposed between two of the adjacent restriction plates 102. The height of each of the restriction plates 102 is greater than the height of the nozzle. The distance and the height difference between the adjacent restriction plates 102 limit a spray range of the nozzle 103 between the adjacent restriction plates.

The nozzle 103 may be a linear nozzle. The nozzle 103 includes a plurality of linearly spaced ejection orifices, and a direction in which the ejection orifices are arranged is perpendicular to a movement direction of the substrate. The lines from the ejection orifice to the two adjacent restriction plates determine an angle. The angle is the angle range in which the nozzle sprays the material. The distance between the substrate and the nozzle 103 determines the area where the nozzle 103 sprays the material on the surface of the substrate. In order to accommodate the different deposition requirements of the substrate, it is necessary to change the area where the material is sprayed by the nozzle 103 on the surface of the substrate. The restriction plates 102 are used to shield a part of the material sprayed by the nozzle 103, so as to control the range where the material is sprayed by the nozzle on the surface of the substrate.

Each of the restriction plates 102 is connected with a moving assembly, each of the restriction plates 102 is movable within a region between two of the adjacent evaporation sources 101 via the moving assembly, thereby adjusting the distance between the restriction plates 102 and the evaporation resources 101, and the heights of the restriction plates 102, thereby controlling the shielded area for the sprayed material.

In the present embodiment, each of the restriction plates 102 is horizontally or vertically movable within the region between two of the evaporation sources 101 via the moving assembly. The moving assembly includes horizontal rails 104 disposed at both ends of one of the evaporation sources 101 and being parallel to a width direction of the evaporation sources 101, and vertical rails 105 being parallel to a height direction of the evaporation sources 101. Moreover, a bottom of each of the vertical rails 105 is slidably connected to one of the horizontal rails 104 via a first drive motor, and each end of each of the restriction plates 102 is slidably connected to one of the vertical rails 105 via a second drive motor.

Each of the horizontal rails 104 includes a horizontal base. First grooves are formed on both sides of the horizontal base. A first connector is slidably disposed on the horizontal base. The first connector includes two parallel supporting plates and a mounting plate connected to the two supporting plates. The mounting plate is located at the upper parts of the support plates, and the lower parts of the two supporting plates is bent inwardly and fitted into the first grooves on both sides of the horizontal base. The first drive motor is disposed on the first connector, the end of the output shaft of the first driving motor is connected with a roller, and the side of the roller is in contact with the surface of the horizontal base.

Each of the vertical rails 105 includes a vertical base. The bottom of the vertical base is fixed onto the surface of the mounting plate of the first connector. Second grooves are formed on both sides of the vertical base. A second connector is slidably disposed on the vertical base. The side of each of the restriction plate 102 is fixed onto the surface of the second connector. A second driving motor is disposed on the second connector. The configuration of the second connector and the connection between the second connector and the vertical base are similar to those of the first connector, and will not be redundantly described here.

A top of each of the restriction plates 102 is provided with a sub-plate, the sub-plate is perpendicular to one of the restriction plates 102, and a side portion of the sub-plate extends toward the upper side of the adjacent evaporation source 101. Without the sub-plate, the range where the restriction plate shields the material sprayed by the nozzle 103 is limited. Even when the adjustment magnitude is great, the effect is still not significant. When the sub-plate is disposed on the top of the restriction plate, the sub-plate moves with the restriction plate 102 in the horizontal direction, and the sub-plate directly interfere with the material sprayed by the nozzle 103, so that the adjustment is convenient and the restriction effect is improved.

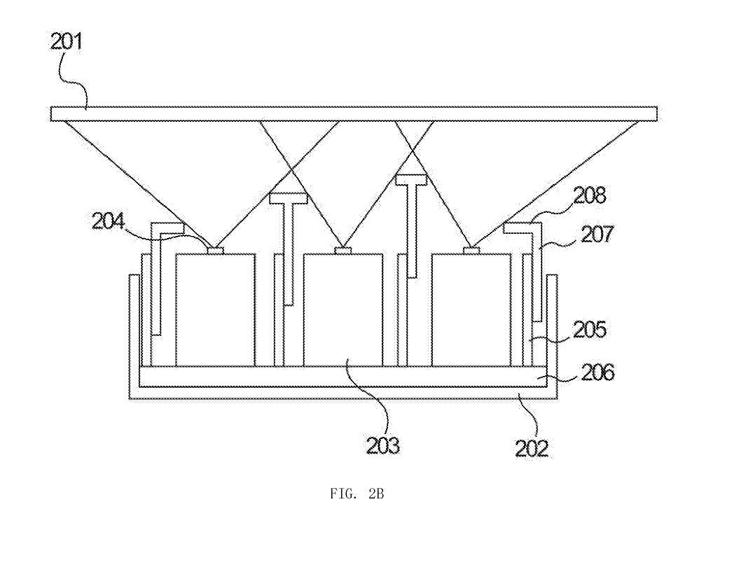

FIG. 2A is a schematic diagrams of the evaporation apparatus in a status of use in the present disclosure.

As shown in FIG. 2A, the substrate 201 passes over the evaporation apparatus. When the substrate 201 is retained directly above the evaporation apparatus, the evaporation apparatus sprays the material toward the substrate 201.

The evaporation apparatus includes the housing 202 in which the evaporation sources 203 are disposed. The nozzles 204 arc disposed on the upper part of the evaporation source 203. The restriction plates 207 are disposed on both sides of the nozzles 204. The bottoms of the vertical rails 205 are connected to the horizontal rails 206. The positions of the restriction plates 207 are adjusted according to the demand of the material deposition for the substrate 201, so that the material sprayed by the nozzle 204 falls into a corresponding area on the substrate 201.

A top of each of the restriction plates 207 is provided with a sub-plate 208.

FIG. 2B is a schematic diagram of the evaporation apparatus in another status of use in the present disclosure.

As shown in FIG. 2B, the difference between FIG. 2A and FIG. 2B is that the size of the substrate 201 is changed. Thus, the positions of the restriction plates 207 are adjusted so that the range of the material sprayed by the nozzle 204 meets the demand of the material deposition for the substrate 201.

In order to recover the material sprayed on the restriction plates, each of the restriction plates is removably provided with an elongated collection trough, the elongated collection trough is parallel to a bottom edge of one of the restriction plates, and two ends of the elongated collection trough are flush with two side edges of one of the restriction plates. The material which is accumulated by the shielding of the restriction plates flows into the elongated collection troughs along the surface of the restriction plates.

Each of the restriction plates is provided with a heating element to prevent the material from being rapidly solidified, so as to assist the material in flowing into the elongated collection trough, when the material is accumulated on the surfaces of the restriction plates.

The two ends of the elongated collection trough are provided with fixing members, and the fixing members are bent, disposed on sides of one of the restriction plates, and fixed by bolts, thereby fixing the elongated collection trough.

An arcuate transition surface is formed at a junction of the sub-plate and one of the restriction plates, so that the material which is accumulated on the surface of the sub-plate flows into the elongated collection trough through the arcuate transition surface.

The arcuate transition surface is an inner circular arcuate surface, one end of the arcuate transition surface is connected to an end of the sub plate, and other end of the arcuate transition surface is connected to a side of one of the restriction plates.

In summary, although the preferable embodiments of the present disclosure have been disclosed above, the embodiments are not intended to limit the present disclosure. A person of ordinary skill in the art, without departing from the spirit and scope of the present disclosure, can make various modifications and variations. Therefore, the scope of the disclosure is defined in the claims.

What is claimed is:

1. An evaporating apparatus, comprising:
a housing; and
a plurality of evaporation sources located in the housing for evaporating a material into material vapor, and each including:
a material chamber for storing the material;
a heating member fixed onto an exterior of the material chamber for heating the material in the material chamber;
a nozzle located on an upper side of one of the evaporation sources for spraying the material vapor onto a surface of a substrate; and
a plurality of restriction plates disposed on both sides of each of the evaporation sources, wherein a height of each of the restriction plates is greater than a height of the nozzle, and wherein a distance and a height difference between the adjacent restriction plates limit a spray range of the nozzle between the adjacent restriction plates;
wherein each of the restriction plates is connected with a moving assembly, each of the restriction plates is movable within a region between two of the adjacent evaporation sources via the moving assembly for adjusting the spray range of the nozzle, each of the restriction plates is horizontally or vertically movable within the region between two of the evaporation sources via the moving assembly, and the moving assembly includes:
horizontal rails disposed at both ends of one of the evaporation sources and parallel to a width direction of the evaporation sources; and
vertical rails parallel to a height direction of the evaporation sources,
wherein a bottom of each of the vertical rails is slidably connected to one of the horizontal rails via a first drive motor, and each end of each of the restriction plates is slidably connected to one of the vertical rails via a second drive motor.

2. The evaporation apparatus as claimed in claim 1, wherein the nozzle is a linear nozzle, the linear nozzle includes a plurality of linearly spaced ejection orifices, and an arrangement direction of the ejection orifices is perpendicular to a movement direction of the substrate.

3. The evaporation apparatus as claimed in claim 1, wherein a top of each of the restriction plates is provided with a sub-plate, the sub-plate is perpendicular to one of the restriction plates, and a side portion of the sub-plate extends toward the upper side of the adjacent evaporation source.

4. The evaporation apparatus as claimed in claim 3, wherein each of the restriction plates is removably provided with an elongated collection trough, the elongated collection trough is parallel to a bottom edge of one of the restriction plates, and two ends of the elongated collection trough are flush with two side edges of one of the restriction plates.

5. The evaporation apparatus as claimed in claim 4, wherein each of the restriction plates is provided with a heating element.

6. The evaporation apparatus as claimed in claim 4, wherein the two ends of the elongated collection trough are provided with fixing members, and the fixing members are bent, disposed on sides of one of the restriction plates, and fixed by bolts.

7. The evaporation apparatus as claimed in claim 4, wherein an arcuate transition surface is formed at a junction of the sub-plate and one of the restriction plates.

8. The evaporation apparatus according to claim 7, wherein the arcuate transition surface is an inner circular arcuate surface, one end of the arcuate transition surface is connected to an end of the sub plate, and other end of the arcuate transition surface is connected to a side of one of the restriction plates.

9. An evaporating apparatus, comprising:
a housing, and
a plurality of evaporation sources located in the housing for evaporating a material into a material vapor, and each including:
a material chamber for storing the material;
a heating member fixed onto an exterior of the material chamber for heating the material in the material chamber;
a nozzle located on an upper side of one of the evaporation sources for spraying the material vapor onto a surface of a substrate; and
a plurality of restriction plates disposed on both sides of each of the evaporation sources, wherein a height of each of the restriction plates is greater than a height of the nozzle, and wherein a distance and a height difference between the adjacent restriction plates limit a spray range of the nozzle between the adjacent restriction plates;
wherein each of the restriction plates is connected with a moving assembly, each of the restriction plates is movable within a region between two of the adjacent evaporation sources via the moving assembly for adjusting the spray range of the nozzle.

10. The evaporation apparatus as claimed in claim 1, wherein the nozzle is a linear nozzle, the linear nozzle includes a plurality of linearly spaced ejection orifices, and an arrangement direction of the ejection orifices is perpendicular to a movement direction of the substrate.

11. The evaporation apparatus as claimed in claim 1, wherein a top of each of the restriction plates is provided with a sub-plate. the sub-plate is perpendicular to one of the restriction plates, and a side portion of the sub-plate extends toward the upper side of the adjacent evaporation source.

12. The evaporation apparatus as claimed in claim 3, wherein each of the restriction plates is removably provided with an elongated collection trough, the elongated collection trough is parallel to a bottom edge of one of the restriction plates, and two ends of the elongated collection trough are flush with two side edges of one of the restriction plates.

13. The evaporation apparatus as claimed in claim 4, wherein each of the restriction plates is provided with a heating element.

14. The evaporation apparatus as claimed in claim 4, wherein the two ends of the elongated collection trough are provided with fixing members, and the fixing members are bent, disposed on sides of one of the restriction plates, and fixed by bolts.

15. The evaporation apparatus as claimed in claim 4, wherein an arcuate transition surface is formed at a junction of the sub-plate and one of the restriction plates.

16. The evaporation apparatus according to claim 7, wherein the arcuate transition surface is an inner circular arcuate surface, one end of the arcuate transition surface is connected to an end of the sub plate, and other end of the arcuate transition surface is connected to a side of one of the restriction plates.
